(19) United States
(12) Patent Application Publication
(10) Pub. No.: US 2010/0332037 A1
(43) Pub. Date: Dec. 30, 2010

(54) INFORMATION PROCESSING APPARATUS, METHOD FOR CONTROLLING INFORMATION PROCESSING APPARATUS

(75) Inventor: Fumio Mikami, Chigasaki-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/823,927

(22) Filed: Jun. 25, 2010

(30) Foreign Application Priority Data
Jun. 30, 2009 (JP) 2009-155314

(51) Int. Cl. G05D 7/06; H05K 5/02

(52) U.S. Cl. 700/282; 454/184

(57) ABSTRACT

Air is blown with a first air amount when a processing unit is not processing a job if a first number of storage units is connected, air is blown with a second air amount when a job is executed. When a second number of storage units is connected, air is blown with a second air amount. The number of storage units connected to an information processing apparatus is detected. When a first number of storage units is detected, and a job is not processed, air blowing is executed using a first air amount. When a job is executed air blowing is executed using a second air amount, which is larger than the first air amount. When a second number of storage units, which is larger than the first number, is detected, air blowing is executed using the second air amount irrespective of whether or not a job is processed.

### BACKGROUND OF THE INVENTION

1. Field of the Invention

The present invention relates to an information processing apparatus, a method for controlling the information processing apparatus, and a control program.

2. Description of the Related Art

Some information processing apparatuses blow air using a fan or the like onto a configuration provided in the information processing apparatus to cool the heat produced thereby. Japanese Patent Application Laid-Open No. 2004-280164 discusses an apparatus configured to control driving of a fan in response to a temperature in an apparatus, according to the performance of a central processing unit (CPU) and a capacity of a hard disk drive (HDD). However, Japanese Patent Application Laid-Open No. 2004-280164 does not discuss control of the rotation speed of the fan according to a number of HDDs. When a temperature sensor is provided and the rotation speed of the fan is controlled according to the temperature, apparatus manufacturing costs increase and reliability of the apparatus is reduced by an increase in a number of components.

When a fan rotation speed is determined according to the maximum number of HDDs that can be connected in an information processing apparatus, and a fan is driven at a constant rotation speed, sometimes the fan is driven at a higher rotation speed than necessary. For example, such a situation occurs when there is a low number of HDDs connected to the information processing apparatus, or when an HDD does not operate when the information processing apparatus is on standby. In this case, excessive cooling is executed, thereby resulting in noise or power consumption due to the driving the fan.

### SUMMARY OF THE INVENTION

According to an aspect of the present invention, an information processing apparatus to which a plurality of storage units can be connected includes an air blowing unit configured to blow air onto the storage units, a processing unit configured to process a job using data stored in the storage unit, a detection unit configured to detect a number of the storage units connected to the information processing apparatus, and a control unit configured to control the air blowing unit to blow air with a different air amount according to whether or not the processing unit is processing a job, when a first number of storage units is detected by the detection unit, and to control the air blowing unit to blow air with the same air amount irrespective of whether or not the processing unit is processing a job, when a second number of storage units, which is larger than the first number, is detected by the detection unit.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 is a block diagram illustrating a configuration of an apparatus according to a first exemplary embodiment of the present invention.

FIG. 2 is a flowchart illustrating a processing of fan driving control according to the first exemplary embodiment.

FIG. 3 is a flowchart illustrating processing of fan driving control according to a second exemplary embodiment.

FIG. 4 is a block diagram illustrating a configuration of an apparatus according to a third exemplary embodiment.

FIG. 5 is a flowchart illustrating processing of fan driving control according to the third exemplary embodiment.

### DESCRIPTION OF THE EMBODIMENTS

Various exemplary embodiments, features, and aspects of the invention will be described in detail below with reference to the drawings.

In the description below, although an example will be described in which mirroring (redundant array of inexpensive disks 1 (RAID1)) is employed as a plurality of hard disks provided in a multifunction peripheral (MFP), other RAID configurations or striping may be used.

Furthermore, in the description below, although an example will be described in which a single fan is used as an air blowing unit, a plurality of fans may be used as an air blowing unit. When a single fan is used as an air blowing unit, an air blowing amount may be adjusted by changing a fan rotation speed. However when a plurality of fans is provided as an air blowing unit, an air blowing amount may be adjusted by changing a number of driven fans rather than by only adjusting a fan rotation speed.

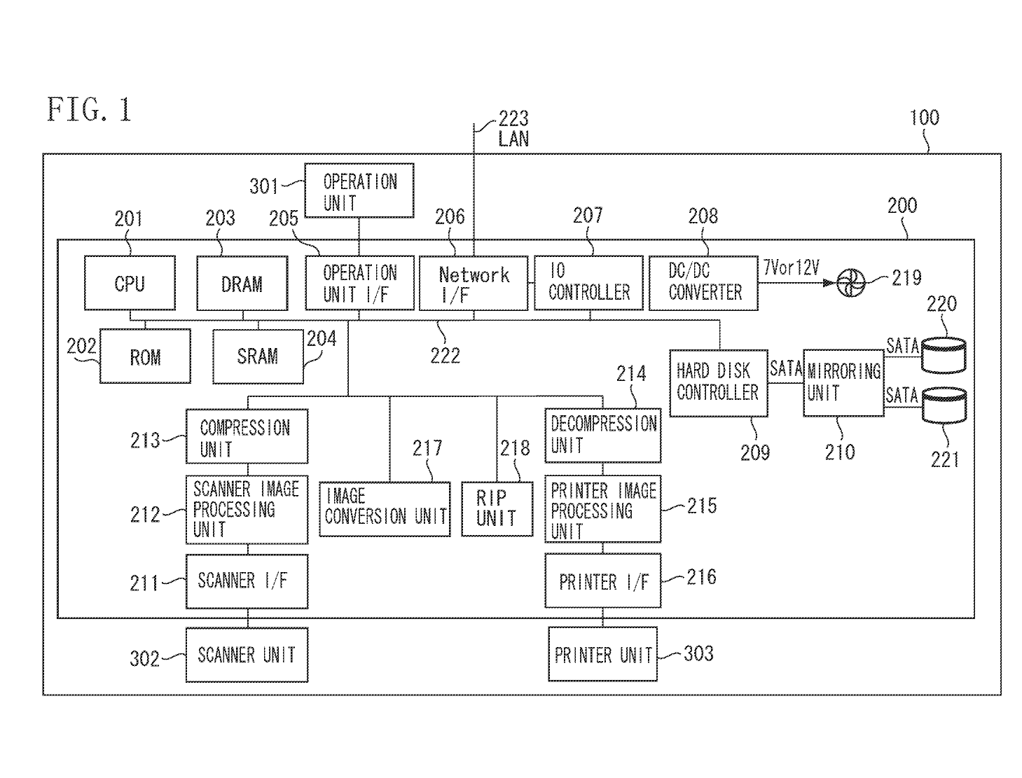

FIG. 1 is a block diagram illustrating a configuration of an apparatus according to a first exemplary embodiment. An MFP 100 includes a system control unit 200, an operation unit 301, a scanner unit 302 and a printer unit 303. The MFP 100 can transmit/receive image data, device information, or the like via a local area network 223 to/from an external apparatus such as a personal computer (PC) or the like.

The MFP 100 is an example of an information processing apparatus and enables connection of a plurality of hard disks (first number, second number). A plurality of air blowing amounts (first air blowing amount, second air blowing amount, third air blowing amount) to the hard disk by a fan (air blowing unit) can be selected.

A CPU 201 controls various configurations of the MFP 100. A read only memory (ROM) 202 stores a boot program for the CPU 201. A dynamic random access memory (DRAM) 203 functions as a work memory (work area) for the CPU 201. A static random access memory (SRAM) 204 stores various pieces of data that are used by the CPU 201 (e.g., settings for mirroring of an HDD described below). The SRAM 204 is backed up by a battery (not illustrated) and can save data when the power source of the MFP 100 is OFF.

An operation unit interface (I/F) 205 is an interface configured to connect a system bus 222 and the operation unit 301. The operation unit I/F 205 outputs image data to the operation unit 301 for display on the operation unit 301, and outputs information input from the operation unit 301 to the system bus 222. A network I/F 206 is connected to the system bus 222 and a LAN 223, and executes input and output of data between the MFP 100 and an external unit.

An IO controller 207 outputs a signal configured to control an output voltage of a DC/DC converter 208 in response to an instruction of the CPU 201. The DC/DC converter 208 supplies 7V (during low-speed rotation) or 12V (during high-speed rotation) to a fan 219 according to the signal. The hard disk controller 209 is connected to a mirroring unit 210 via a serial advanced technology attachment (SATA) interface.

The mirroring unit 210 is connected with a hard disk 220 and a hard disk 221 via the SATA interface. The hard disk 220 and the hard disk 221 store system software, image data, or the like. The hard disk 220 and the hard disk 221 are controlled by mirroring so that data stored in both hard disks are the same. Using of the hard disk 220 and the hard disk 221 can prevent system failure resulting from a fault in one of the HDDs, since when one hard disk fails the other can be used.

A scanner I/F 211 sends image data read by the scanner unit 302 to a scanner image processing unit 212. The scanner image processing unit 212 separates the image data, which is sent from the scanner I/F 211, into block units to thereby generate tile data. A compression unit 213 compresses image data that has been image processed by the scanner image processing unit 212. The compressed image data is stored in the hard disk 220 and the hard disk 221.

A decompression unit 214 decompresses image data stored in the hard disk 220 and the hard disk 221. A printer image processing unit 215 rasterizes the image data, which is formed by the tile data decompressed by the decompression unit 214. The printer I/F 216 sends image data, which has been image processed by the printer image processing unit 215, to a printer unit 303.

An image conversion unit 217 executes image processing on the image data stored in the hard disk 220 and the hard disk 221 as necessary. A routing information protocol (RIP) unit 218 executes rendering on the image data of the page description language (PDL) input from an external apparatus.

A fan 219 prevents temperature increase in the system control unit 200 due to heat produced by the hard disk 220 and the hard disk 221 by blowing air on the hard disk 220 and the hard disk 221. The fan 219 may blow air in the periphery of the hard disk 220 and the hard disk 221 to the outside.

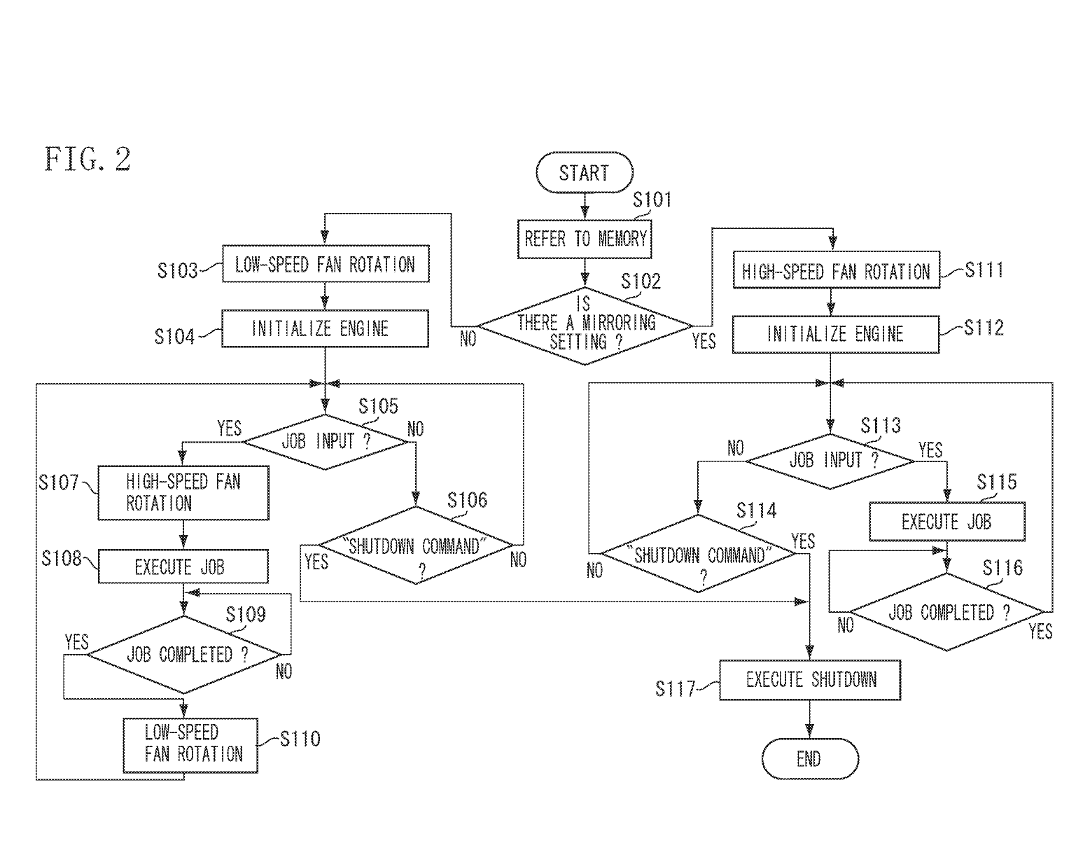

FIG. 2 is a flowchart illustrating processing of fan driving control according to the first exemplary embodiment. The processing illustrated in the flowchart in FIG. 2 is executed by a CPU 201, which reads a program stored in the ROM 202 into the DRAM 203. In the description below, the term “job” globally refers to an operation job using the operation unit 301, a scanning job using the scanner 302, a printing job using the printer unit 303, and an inquiry job using the Network I/F 206.

The flowchart is started when the power source of the MFP 100 is ON.

Firstly, in step S101, the CPU 201 refers to the mirroring settings stored in the SRAM 204, and detects the number of hard disks connected to the MFP 100. The mirroring settings may either execute mirroring or not execute mirroring, and may be arbitrarily set by service personnel or the like. When mirroring is not executed, that corresponds to the state where one hard disk is connected to the MFP 100, and when mirroring is executed, that corresponds to the state where two (or a plurality of) hard disks are connected to the MFP 100.

In step S102, the CPU 201 determines whether or not there is a setting for execution of mirroring based on the result obtained in step S101. In step S102, when it is determined that processing of mirroring is set (YES in step S102), the processing proceeds to S111. On the other hand, in step S102, when it is determined that execution of mirroring is not set (NO in step S102), the processing proceeds to S103.

In step S102, when it is determined that processing of mirroring is not set, in step S103, the CPU 201 executes low-speed rotation of the fan 219 by instructing the IO controller 207 to output a 7V output from the DC/DC converter 208. Then in step S104, the CPU 201 initializes the engine of the printer unit 303, and transfers the MFP 100 to a standby state.

Then, in step S105, the CPU 201 determines whether or not a job is input to the MFP 100. In step S105, when it is determined that a job is input to the MFP 100 (YES in step S105), the processing proceeds to step S107. In step S105, when it is determined that a job is not input to the MFP 100 (NO in step S105), the processing proceeds to step S106.

In step S105, when it is determined that a job is not input to the MFP 100 (NO in step S105), in step S106, the CPU 201 determines whether or not the MFP 100 has been instructed to shutdown. In step S106, when the CPU 201 determines that the MFP 100 has been instructed to shutdown (YES in step S106), the processing proceeds to step S117. In step S106, when the CPU 201 determines that the MFP 100 has not been instructed to shutdown (NO in step S106), the processing proceeds to step S105.

In step S105, when it is determined that a job is input to the MFP 100 (YES in step S105), in step S107, the CPU 201 executes high-speed rotation of the fan 219 by instructing the IO controller 207 to output a 12V output from the DC/DC converter 208.

Then in step S108, the CPU executes processing of the input job. Thereafter in step S109, the CPU 201 determines whether or not the job processing has been completed. In step S109, when it is determined that the job processing has been completed (YES in step S109), the processing proceeds to step S110. In step 109, when it is determined that the job processing has not been completed (NO in step S109), the CPU 201 is placed on a standby mode until completion of job processing.

In step S109, when it is determined that the job processing has been completed (YES in step S109), in step 110, the CPU 201 executes low-speed rotation of the fan 219 by instructing the IO controller 207 to output a 7V output from the DC/DC converter 208.

In step S102, when it is determined that the execution of mirroring is set (YES in step S102), in step S111, the CPU 201 executes high-speed rotation of the fan 219 by instructing the IO controller 207 to output a 12V output from the DC/DC converter 208.

Then, in step S112, the CPU 201 initializes the engine of the printer unit 303, and transfers the MFP 100 to a standby state. Then in step S113, the CPU 201 determines whether or not a job is input to the MFP 100. In step S113, when it is determined that a job is input to the MFP 100 (YES in step S113), the processing proceeds to step S115. In step S113, when it is determined that a job is not input to the MFP 100 (NO in step S113), the processing proceeds to step S114.

In step S113, when it is determined that a job is not input to the MFP 100 (NO in step S113), in step S114, the CPU 201 determines whether or not the MFP 100 has been instructed to shutdown. In step S114, when the CPU 201 determines that the MFP 100 has been instructed to shutdown (YES in step S114), the processing proceeds to step S117. In step S114, when the CPU 201 determines that the MFP 100 has not been instructed to shutdown (NO in step S114), the processing proceeds to step S113.

In step S113, when it is determined that a job is input to the MFP 100 (YES in step S113), in step S115, the CPU 201 executes processing of the input job. During job processing in step S115, the fan 219 may execute high-speed rotation at a rotation speed, which is higher than the normal high-speed rotation.

In step S116, the CPU 201 determines whether or not the job processing is completed. In step S116, when it is determined that job processing has been completed (YES in step S116), the processing proceeds to step S113. In step S116, when it is determined that the job processing has not been completed (NO in step S116), the CPU 201 is placed in a standby state until the completion of the job processing. In step S106 or step S114, when it is determined that a shutdown command has been sent to the MFP 100 (YES in step S106 or step S114), in step S117, the CPU 201 executes shutdown processing of the MFP 100.

As described above, in the present exemplary embodiment, the driving of the fan is controlled according to whether or not mirroring is set. More specifically, when mirroring is set, the fan is normally driven at a high rotation speed. When mirroring is not set, the fan is driven at a low-speed rotation during a standby state, and is driven at a high-speed during job execution.

The high rotation speed in step S107 and the high rotation speed during step S111 may be a different rotation speed. During execution of the job processing in step S115, the fan 219 may execute high-speed rotation at a rotation speed that is higher than the normal high-speed rotation.

The fan driving control described above is determined according to the considerations described below. The MFP drives the hard disk during standby mode in preparation for a job to be input. Consequently, even during the standby state, cooling by the fan is required for a predetermined amount of heat produced by the hard disk. During job execution, since the hard disk is accessed, the heat generation amount of the hard disk is large. Since operation noise is produced by the MFP, the noise produced by the fan is not conspicuous. Thus during job execution, the fan is driven at a high-speed.

During the standby state (when a single hard disk is used), since the hard disk is not accessed, the heat generation amount of the hard disk is low. Since operation noise is not produced by the MFP, the noise produced by the fan becomes a conspicuous part of the noise produced by the MFP during the standby state. Since there is a demand to minimize this noise in an office or the like, during the standby state (when a single hard disk is used), the fan is driven at a low-speed.

During the standby state (when two hard disks are used), although the hard disks are not accessed, the generated heat amount in the hard disks increases. The standard configuration of the apparatus uses a single hard disk, and this type of quiet operation is most required. Two hard disks are used when data reliability is important and there is a product setting in which an increase in noise is allowed as an exception to the standard specification. Thus, during the standby state (when two hard disks are used), the fan is driven at a high-speed.

According to the first exemplary embodiment, when a single hard disk is used, the rotation speed of the fan during the standby state is reduced to thereby enable reduction of noise resulting from the driving of the fan.

The first exemplary embodiment is characterized by the point that the number of hard disks connected to the apparatus is determined using a mirroring setting stored in the SRAM. On the other hand, the second exemplary embodiment is characterized by the point that the number of hard disks connected to the apparatus is determined using a SATA interface. Since the configuration of the apparatus according to the second exemplary embodiment is similar to the configuration of the apparatus according to the first exemplary embodiment (described above with reference to FIG. 1), description thereof will be omitted.

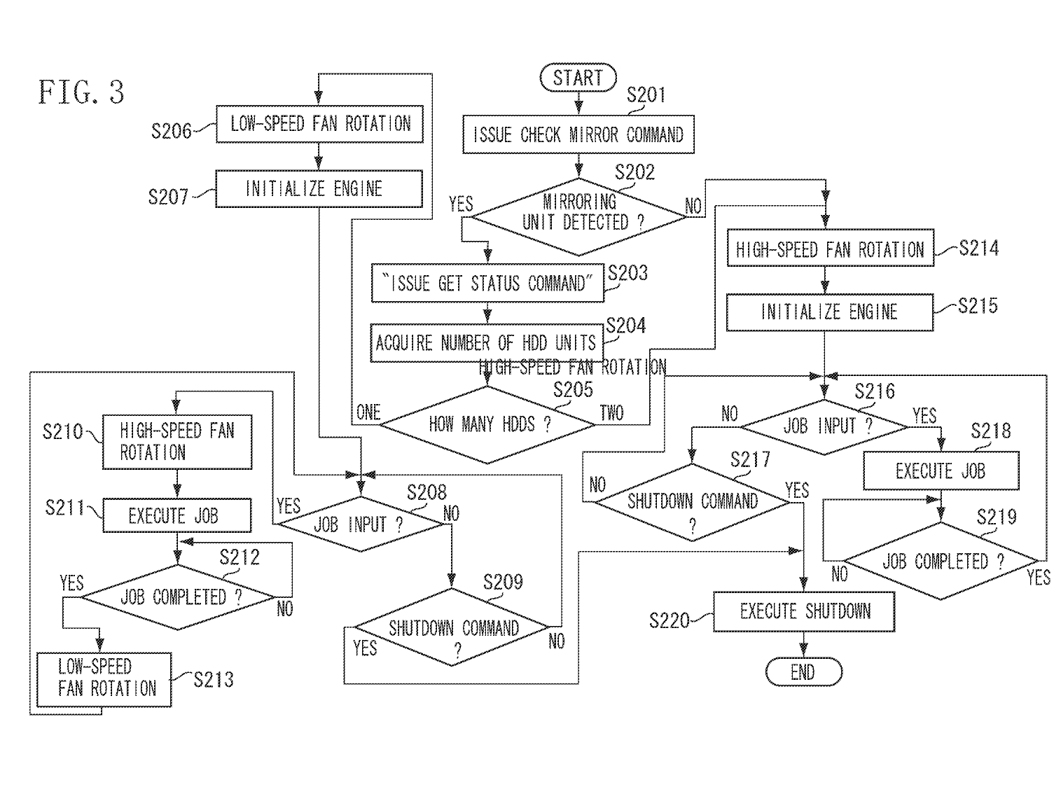

FIG. 3 is a flowchart illustrating processing of fan driving control according to the second exemplary embodiment. The process illustrated in the flowchart in FIG. 3 is executed by a CPU 201, which reads a program stored in the ROM 202 into the DRAM 203. In FIG. 3, steps S206 to S202 are the same processing as the steps S103 to S117 of the first exemplary embodiment. Therefore, additional description thereof will be omitted.

First, in step S201, the CPU 201 sends a “check mirror command”, which is a unique command for the mirroring unit, to the SATA interface. Upon receipt of the “check mirror command” from the CPU 201, the SATA interface detects the mirroring unit, and sends the detection result to the CPU 201.

Then, in step S202, the CPU 201 determines whether or not a mirroring unit has been detected based on the result of the “check mirror command”. In step S202, when a mirroring unit is detected (YES in step S202), the processing proceeds to step S203. In step S202, when a mirroring unit is not detected (NO in step S202), the processing proceeds to step S214.

In step S202, when it is determined that a mirroring unit is detected (YES in step S202), in step S203, the CPU 201 sends a “get status command”, which is a unique command for the mirroring unit, to the SATA interface.

Upon receipt of the “get status command” from the CPU 201, the SATA interface confirms the number of hard disks connected to the mirror unit, and sends the detection result to the CPU 201. Then, in step S204, the CPU 201 acquires the number of hard disks connected to the mirror unit based on the result of the “get status command”.

Then, in step S205, the CPU 201 determines how many hard disk units are connected to the mirroring unit based on the result of step S204. In step S205, when it is determined that there is one hard disk connected to the mirroring unit (one in step S205), the processing proceeds to step S206. In step S205, when it is determined that there are two hard disks (a plurality of hard disks) connected to the mirroring unit (two in step S205), the processing proceeds to step S214.

According to the second exemplary embodiment, since the connection state of the hard disk is automatically acquired to thereby control the driving of the fan, suitable fan driving control can be achieved according to the change of the number of connected hard disks.

The first exemplary embodiment is characterized by determining the number of hard disks connected to the apparatus based on the setting of the mirroring stored in the SRAM. On the other hand, a third exemplary embodiment is characterized by the point that the number of hard disks connected to the apparatus is determined using a switch connected to the hard disks.

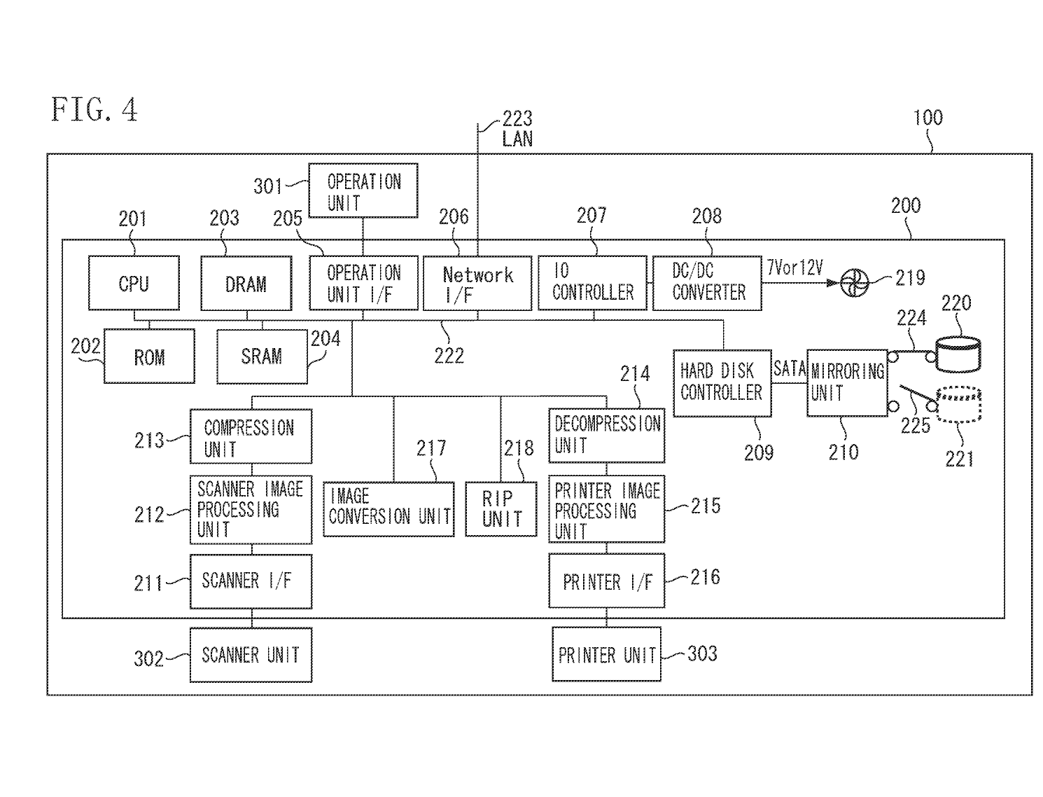

FIG. 4 is a block diagram illustrating a configuration of an apparatus according to the third exemplary embodiment. In FIG. 4, reference numerals 100 to 223 denote the similar units that perform similar operations as the first exemplary embodiment, and therefore additional description thereof will be omitted.

A micro-switch 224 switches the connection state of the mirroring unit 210 and the hard disk 220 between ON and OFF. The micro-switch 225 switches the connection state of the mirroring unit 210 and the hard disk 220 between ON and OFF. The micro-switch 224 and the micro-switch 225 transmit to the CPU 201 a signal indicating whether or not the hard disk is connected to the CPU 201 via the IO controller 207.

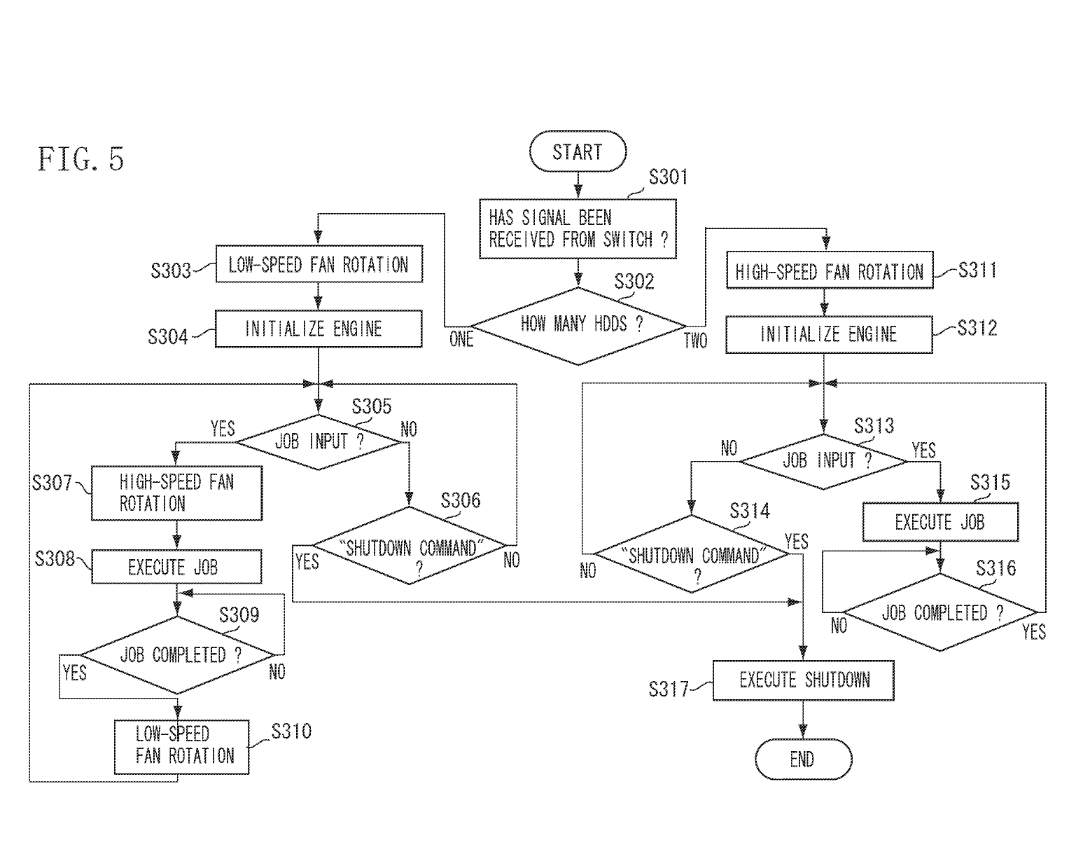

FIG. 5 is a flowchart illustrating processing of fan driving control according to the third exemplary embodiment. The process illustrated in the flowchart in FIG. 5 is executed by a CPU 201, which reads a program stored in the ROM 202 into the DRAM 203. In FIG. 5, the processing in steps S303 to S317 is similar to the processing in steps S103 to S117 in the first exemplary embodiment, and therefore additional description thereof will be omitted.

Firstly, in step S301, the CPU 201 receives a signal indicating whether or not a hard disk is connected from the micro-switch 224 and the micro-switch 225 via the IO controller. Then in step S302, the CPU 201 determines how many hard disks are connected to the mirroring unit based on the signal received in step S301.

In step S302, when it is determined that one hard disk is connected to the mirroring unit (one in step S302), the processing proceeds to step S303. In step S302, when it is determined that two (a plurality) hard disks are connected to the mirroring unit (two in step S302), the processing proceeds to step S311.

According to the third exemplary embodiment, since the connection state can be confirmed when a hard disk is connected, even a hard disk, which cannot be used by a fault or the like, is counted in the number of connected hard disks.

The first exemplary embodiment is characterized by determining the number of hard disk connected to the apparatus based on the setting of the mirroring stored in the SRAM. On the other hand, a fourth exemplary embodiment is characterized by the point that the number of hard disks connected to the apparatus is determined via a current detection device connected to the hard disk.

The configuration of the apparatus according to the fourth embodiment substitutes the micro-switch 224 and the micro-switch 225 in the configuration of the apparatus according to the third exemplary embodiment respectively for a current detection device 26 and a current detection device 227.

The processing of fan driving control according to the fourth embodiment substitutes the micro-switch 224 and the micro-switch 225 at step S301 in the processing of fan driving control according to the third exemplary embodiment (described above using FIG. 5) for the current detection device 26 and the current detection device 227.

A number of operating hard disks is acquired by detecting a power source current of the hard disks. According to the fourth exemplary embodiment, since the connection state can be confirmed when a current is applied to a hard disk, a hard disk, which cannot be used due to a fault or the like, is not counted in the number of connected hard disks.

The first exemplary embodiment is characterized by the point that the fan in driven with high-speed rotation irrespective of the operation state of the two hard disks when it is determined that there are two hard disks. On the other hand, a fifth exemplary embodiment is characterized by the point that, when it is determined that there are two hard disks, the fan is driven at a high rotation speed when both the two hard disks are driven, and when only one of the hard disks is driven, the fan is driven at a low rotation speed.

The configuration of the apparatus according to the fifth exemplary embodiment is similar to the configuration of the apparatus according to the first exemplary embodiment, and therefore additional description thereof will be omitted.

Although the processing of fan driving control of the apparatus according to the fifth exemplary embodiment is basically similar to the processing of fan driving control according to the first exemplary embodiment (described above with reference to FIG. 2), only the different points are described below.

In the fifth exemplary embodiment, in steps S111 to S116, power to the two hard disks is supplied only when access to the two hard disks is required. In other cases, power is supplied to one hard disk. When power is supplied to two hard disks, the fan is rotated at a high rotation speed, and when power is supplied to one hard disk, the fan is rotated at a low rotation speed.

Access is required to two hard disks, for example, when a job is executed, when writing data into a hard disk, or when executing a rebuild process or restore process for mirroring. Access is not required to two hard disks, for example, when a job is not executed, when data is read from a hard disk, or when a rebuild process or restore process for mirroring is not executed.

According to the fifth exemplary embodiment, a reduction in noise resulting from driving the fan when one hard disk is operated can be achieved, by operating the fan at a high rotation speed only when two hard disks are operated.

Aspects of the present invention can also be realized by a computer of a system or apparatus (or devices such as a CPU or MPU) that reads out and executes a program recorded on a memory device to perform the functions of the above-described embodiments, and by a method, the steps of which are performed by a computer of a system or apparatus by, for example, reading out and executing a program recorded on a memory device to perform the functions of the above-described embodiments. For this purpose, the program is provided to the computer for example via a network or from a recording medium of various types serving as the memory device (e.g., computer-readable medium). In such a case, the system or apparatus, and the recording medium where the program is stored, are included as being within the scope of the present invention.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2009-155314 filed Jun. 30, 2009, which is hereby incorporated by reference herein in its entirety.

What is claimed is:

1. An information processing apparatus to which a plurality of storage units can be connected, the information processing apparatus comprising:
an air blowing unit configured to blow air onto the storage units;
a processing unit configured to process a job using data stored in the storage unit;
a detection unit configured to detect a number of the storage units connected to the information processing apparatus; and
a control unit configured to control the air blowing unit to blow air with a different air amount according to whether or not the processing unit is processing a job, when a first number of storage units is detected by the detection unit, and to control the air blowing unit to blow air with the same air amount irrespective of whether or not the processing unit is processing a job, when a second number of storage units, which is larger than the first number, is detected by the detection unit.

2. The information processing apparatus according to claim 1, wherein, in a case where a first number of storage units is detected by the detection unit, and when the processing unit is not processing a job, the control unit controls the air blowing unit to blow air with the first air amount, and when the processing unit is processing a job, the control unit controls the air blowing unit to blow air with a second air amount, which is larger than the first air amount, and in a case where a second number of storage units, which is larger than the first number, is detected by the detection unit, the control unit controls the air blowing unit to blow air with the second air amount irrespective of whether or not the processing unit is processing a job.

3. The information processing apparatus according to claim 2, wherein in a case where the second number of storage units is detected by the detection unit, the control unit controls the air blowing unit to blow air with the second air amount when all the second number of storage units are operating, and when any one of the second number of storage units is not operating, the control unit controls the air blowing unit to blow air with a third air amount, which is larger than the first air amount and smaller than the second air amount.

4. The information processing apparatus according to claim 1, wherein the air blowing unit controls the air amount for air blowing by controlling a rotation speed of a fan.

5. The information processing apparatus according to claim 1, wherein the first number is one and the second number is two.

6. The information processing apparatus according to claim 1, wherein the second number of storage units is used to execute mirroring.

7. A control method for an information processing apparatus to which a plurality of storage units can be connected, and which includes an air blowing unit configured to blow air onto the storage units, and a processing unit configured to process a job using data stored in a storage unit, the method comprising:
detecting a number of the storage units connected to the information processing apparatus; and
controlling the air blowing unit to blow air with a different air amount according to whether or not the processing unit is processing a job, when a first number of storage units is detected, and controlling the air blowing unit to blow air with the same air amount irrespective of whether or not the processing unit is processing a job, when a second number of storage units, which is larger than the first number, is detected.

8. A computer-readable storage medium storing computer-executable instructions for causing an information processing apparatus, to which a plurality of storage units can be connected, and which includes an air blowing unit configured to blow air onto the storage units, and a processing unit configured to process a job using data stored in a storage unit, to execute a control method, the method comprising:
detecting a number of the storage units connected to the information processing apparatus
controlling the air blowing unit to blow air with a different air amount according to whether or not the processing unit is processing a job, when a first number of storage units is detected, and controlling the air blowing unit to blow air with the same air amount irrespective of whether or not the processing unit is processing a job, when a second number of storage units, which is larger than the first number, is detected.
